(19) United States
(12) Patent Application Publication
(10) Pub. No.: US 2008/0302783 A1
(43) Pub. Date: Dec. 11, 2008

(54) Actively controlled embedded burn-in board thermal heaters

(76) Inventors: Anthony Yeh Chiing Wong, Pulau Penang (MY); Christopher Wade Ackerman, Phoenix, AZ (US); James C. Shipley, Gilbert, AZ (US); Hon Lee Kon, Penang (MY)

Correspondence Address: TROP PRUNER & HU, PC, 1616 S. VOSS ROAD, SUITE 750, HOUSTON, TX, 77057-2631, US

(21) Appl. No.: 11/811,307

(22) Filed: Jun. 8, 2007

(51) Int. Cl. H05B 1/02; G01R 31/28

(52) U.S. Cl. 219/494; 219/482; 219/484; 324/755; 324/760; 324/765

(57) ABSTRACT

In one embodiment, a test board includes a plurality of socket locations each to receive a corresponding burn-in socket which in turn is to receive a semiconductor device under test (DUT). Each of the socket locations includes a heating element embedded within the test board, which may be used to provide thermal conduction to the DUT during a burn-in test. Other embodiments are described and claimed.

### BACKGROUND

Many semiconductor devices such as processors, chipsets, and so forth often go through extensive testing after manufacture to verify performance levels and prevent devices likely to fail from being shipped. To perform high volume manufacturing (HVM) testing, so-called burn-in boards are used which include a number of burn-in sockets in which completed semiconductor devices can be inserted to perform the burn-in testing. During burn-in testing, oftentimes an external thermal control unit is coupled to the burn-in board to heat the burn-in board and thus the associated semiconductor devices to a high temperature for the burn-in testing process. However, such external thermal control units require complex mechanical engagement systems and critical alignment. Furthermore, the heaters of such a unit have a fixed matrix that causes the burn-in socket density on the burn-in board to be non-configurable.

Furthermore, while such burn-in boards have been developed for testing high power devices, current semiconductor trends are to provide semiconductor devices that operate at lower power levels such as low power microprocessors, ultra mobile personal computer (UMPC) devices, network communication devices and so forth. Burn-in systems developed for high power systems are costly and are used to support burn-in of power devices greater than approximately 200 Watts. In contrast, lower power products typically have power requirements less than 100 Watts and often less than 30 Watts. It is difficult to perform burn-in of low power products on high power systems. For example, to test low power devices on a high power system, a longer burn-in time is needed, as typically a thermal control system may not be available for testing such low power devices.

### BRIEF DESCRIPTION OF THE DRAWINGS

FIG. 1 a block diagram of a burn-in board in accordance with one embodiment of the present invention.

FIG. 2 is a block diagram of a thermal control system in accordance with an embodiment of the present invention.

FIG. 3 is a flow diagram of a method in accordance with one embodiment of the present invention.

### DETAILED DESCRIPTION

In various embodiments, one or more heater elements may be embedded within a burn-in board (BIB) such as a printed circuit board (PCB) to provide a thermal solution to a device under test (DUT). Thermal levels may be controlled via active temperature sensing feedback, and individual heating elements may be individually controlled. In some embodiments, the heating elements may take the form of embedded metal heater traces located underneath each burn-in socket (BIS) of the burn-in board. In this way, the heating elements may be directly underneath a DUT to enable conduction through the BIS to the DUT.

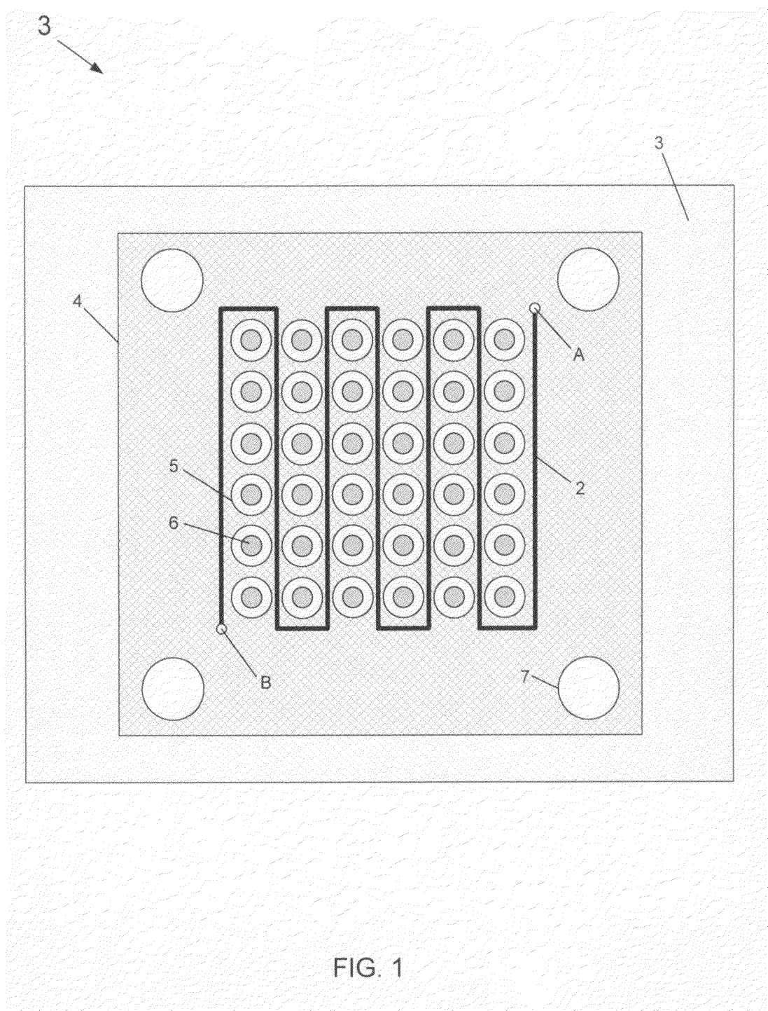

Referring now to FIG. 1, shown is a block diagram of a burn-in board in accordance with one embodiment of the present invention. As shown in FIG. 1, BIB 3, which may be a multi-layer circuit board such as a PCB, may include various circuitry to route power and other connections to a plurality of DUTs to be adapted into burn-in sockets on BIB 3. Note that the portion of BIB 3 shown in FIG. 1 may correspond to that part of a board on which a single burn-in socket is to be adapted. Thus as shown in FIG. 1, a burn-in socket may have a footprint 4 in which are included a plurality of mounting holes 7 for mounting of the BIS. Furthermore, a plurality of pin holes 5 may form an array, i.e., for receipt of pins of a BIS pin array 6.

As shown in FIG. 1, a heating element 2 may be designed with a substantially serpentine form from a positive port A to a negative port B. In various embodiments, heating element 2 may be formed of a metal trace deposited or otherwise formed in a given layer of BIB 3. In various embodiments, such a metal trace may be formed of a copper or other metal. The trace may be fabricated using standard deposition or electroplating processes, in some embodiments. Using heating element 2, conduction heat may be provided to a DUT through the BIS to be adapted onto BIB 3, such as through pins 6 of the pin array.

In various embodiments, the length, thickness, width and quantity of such metal traces may be optimized to achieve a targeted heater power by applying power to the positive and negative ports (i.e., ports A and B) of a trace using one or more power supplies, such as an existing voltage regulation module within burn-in equipment such as a control unit adapted to BIB 3. In various embodiments, by restricting heating elements 2 only to pin arrays of burn-in sockets, so-called hot spots of a heater may be eliminated and reliability may be further increased.

Thus each location of a burn-in board over which a burn-in socket is to be adapted may include a heating element in accordance with an embodiment of the present invention. Because DUTs having different performance characteristics may be adapted to the burn-in sockets during burn-in testing, individual control of the heating elements may be realized, in some embodiments.

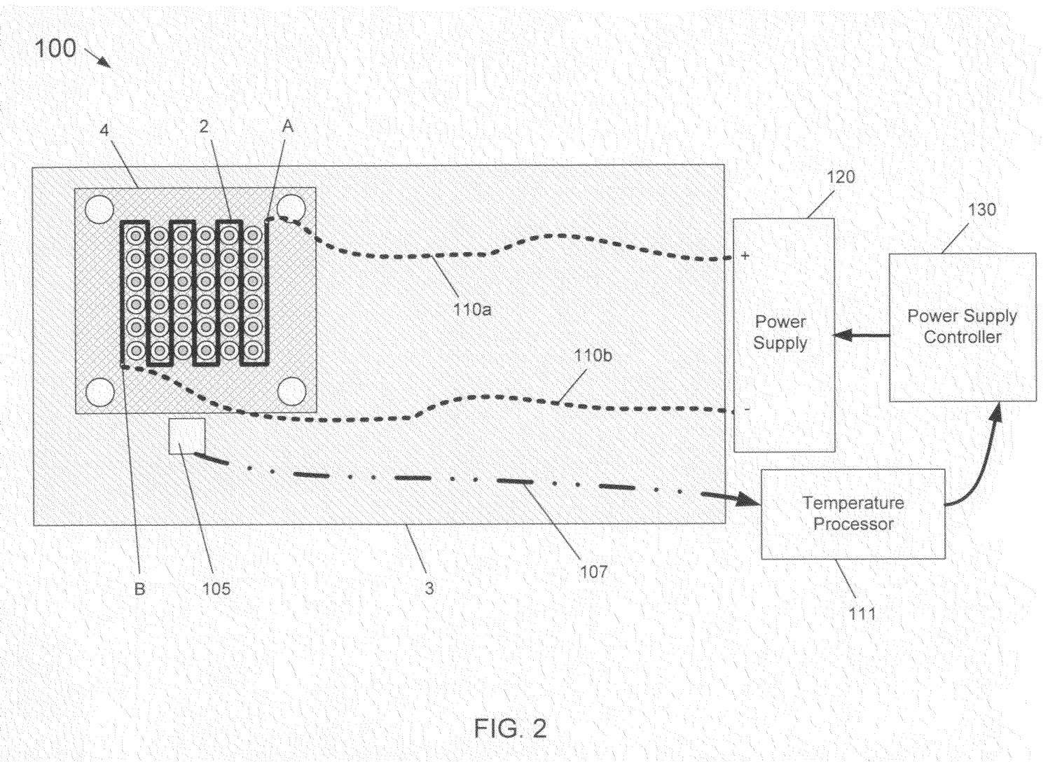

Referring now to FIG. 2, shown is a block diagram of a thermal control system in accordance with an embodiment of the present invention. As shown in FIG. 2, thermal control system 100 may be used to individually monitor and control the thermal profile of each of multiple burn-in sockets adapted to a burn-in board. While shown in the embodiment of FIG. 2 with only a single such heating element and burn-in socket location for ease of illustration, understand the scope of the present invention is not limited in this regard and in various embodiments many such heating elements and burn-in sockets may be present. Note that the same reference numerals used in FIG. 1 are used in FIG. 2 to refer to the same components. As shown in FIG. 2, BIB 3 includes a heating element 2 having ports A and B that are coupled to, respectively, positive and negative voltage supply lines 110ₐ and 110_{b}. Accordingly, heating element 2 receives power from a power supply 120 that in turn is controlled by a power supply controller 130. Understand that while only this single heating element 2 is shown coupled to supply lines 110ₐ and 110_{b}, multiple such heating elements may be adapted to these voltage supply lines.

Power to heating element 2 may be controlled by applying a selective voltage level to power supply 120. To determine a desired level, feedback information obtained from a temperature sensor 105 may be provided via a feedback line 107 to a temperature processor 111. Note that temperature sensor 105 may be placed in close proximity to the heater trace (and the burn-in socket (and thus a DUT thereon) to measure temperature emanating from the DUT. Furthermore, thermal sensor 105 may provide information regarding its own temperature, which may also closely correspond to that of the associated heating element 2. Based on this information, temperature processor 111 may process the data and send commands to power supply controller 130, which in turn may control the voltage provided by power supply 120 accordingly. Thus power supply controller 130 may provide information to adjust the power supply voltage level to match a desired temperature or may turn off power supply 120 completely if the detected temperature exceeds a threshold value.

Note that while shown with these limited components in the embodiment of FIG. 2, additional components may be present in a given burn-in system. For example, multiple power supplies may be present, with power supply 120 shown in FIG. 2 being a secondary power supply. That is, during testing of high power devices, both a primary power supply (not shown in FIG. 2) and power supply 120 may be used to provide power to the semiconductor DUTs in each of the burn-in sockets on burn-in board 3, under control of power supply controller 130. However, during testing of lower power devices, power requirements are lower and thus both power supplies are not needed to power the devices. Instead, one of the power supplies, e.g., power supply 120 may be controlled to instead provide power via voltage supply lines 110a and 110b to the various heater elements 2 associated with each burn-in socket. Accordingly, a switch or other selection means may be present to enable providing the power to either semiconductor DUTs or corresponding heater elements based on a type of test to be run on the devices, as well as based on a type of DUT. Accordingly, heater elements 2 of burn-in board 3 may be enabled for certain test operations, such as testing of low power devices while such heater elements may be disabled for other testing, such as testing of high powered devices.

While shown with this particular implementation in the embodiments of FIGS. 1 and 2, understand the scope of the present invention is not limited in this regard and in various embodiments, different configurations for heater elements as well as sensing and control circuitry may be realized. Furthermore, understand that different types of thermal sensors as well as temperature processors, power supplies and controllers may be implemented, both on a given burn-in board or associated therewith such as a separate control circuit for the burn-in board.

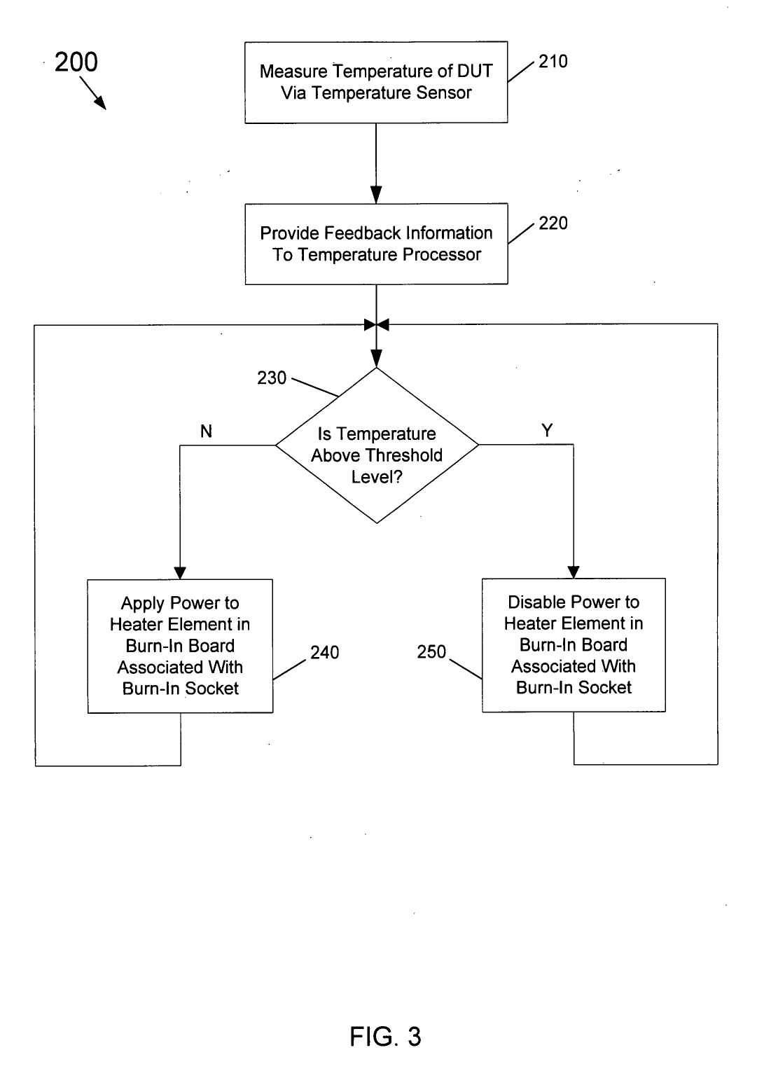

Referring now to FIG. 3, shown is a flow diagram of a method in accordance with one embodiment of the present invention. As shown in FIG. 3, method 200 may be performed to control the temperature of each individual DUT located in a burn-in socket coupled to a burn-in board individually. As shown in FIG. 3, method 200 may begin by measuring a temperature of the DUT via a temperature sensor (block 210). Feedback information regarding the temperature may be provided to a temperature processor (block 220). For example, signal traces within the burn-in board may be provided from the temperature sensor to a temperature processor, which may be located in an external control unit coupled to the burn-in board. Next, it may be determined whether the temperature is above a threshold level (diamond 230). Such a threshold level may vary depending on a type of semiconductor device (e.g., low power/high power device), burn-in testing process and so forth. Based on the temperature, power may be applied to a heater element in the burn-in board associated with the burn-in socket (block 240), if the temperature is not above the threshold level, otherwise such power may be disabled (block 250). As shown in FIG. 3, from both the blocks 240 and 250, control may pass back to diamond 230. While shown with this particular implementation in the embodiment of FIG. 3, the scope of the present invention is not limited in this regard.

By providing thermal heat through conduction to DUTs, such as low power devices, the time required during a burn-in test for the device to achieve its burn-in junction temperature may be shorter, thus reducing overall burn-in time. Furthermore, the need for an expensive external thermal control array may be avoided. In addition to the costs for such a thermal control array, space may be minimized and furthermore, flexibility of burn-in board device density may also be achieved.

For example, in some implementations between four and seven times burn-in time reduction may be realized depending on DUT power, leading to an equivalent amount of tooling utilization improvements. In various embodiments, a burn-in time calculation may be in accordance with Equation 1:

$${BIT}_{B} = \frac{{BIT}_{A}}{{e}^{( \frac{{E}_{a}}{k} ( \frac{1}{{T}_{A}} - \frac{1}{{T}_{B}} ) )}} \qquad [ EQ . 1 ]$$

where BIT_{A} and BIT_{B} correspond to burn-in times for a burn-in test without heaters and with heaters in accordance with one embodiment of the present invention, respectively, Ea (Thermal activation energy) which is typically 0.6 electron volts (eV), k (Boltzmann's constant) is 8.6×10−5 eV/Kelvin (K), and T_{A} and T_{B} are Burn In Temperatures in absolute temperature (K), achieved during such testing.

Using embodiments of the present invention, it is modeled that a 10 Watt device may achieve a T_{A} of 51 degrees Celsius (C) without an embodiment of the present and a T_{B} of 79 C with an embodiment of the present invention. In this way, an improvement of approximately 5.5 times may be realized.

Embodiments may be implemented in code and may be stored on a storage medium having stored thereon instructions which can be used to program a system to perform the instructions. The storage medium may include, but is not limited to, any type of disk including floppy disks, optical disks, compact disk read-only memories (CD-ROMs), compact disk rewritables (CD-RWs), and magneto-optical disks, semiconductor devices such as read-only memories (ROMs), random access memories (RAMs) such as dynamic random access memories (DRAMs), static random access memories (SRAMs), erasable programmable read-only memories (EPROMs), flash memories, electrically erasable programmable read-only memories (EEPROMs), magnetic or optical cards, or any other type of media suitable for storing electronic instructions.

While the present invention has been described with respect to a limited number of embodiments, those skilled in the art will appreciate numerous modifications and variations therefrom. It is intended that the appended claims cover all such modifications and variations as fall within the true spirit and scope of this present invention.

What is claimed is:

1. An apparatus comprising:
a test board having a plurality of layers, the test board including a plurality of socket locations, each to receive a corresponding burn-in socket which in turn is to receive a semiconductor device under test (DUT), wherein each of the plurality of socket locations includes a heating element embedded within the test board, the test board including at least a first voltage supply line and a second voltage supply line coupled to each of the heating elements.

2. The apparatus of claim 1, wherein the heating element comprises a heater trace formed in a layer of the test board, the test board comprising a printed circuit board (PCB).

3. The apparatus of claim 2, wherein the heater trace has a substantially serpentine shape, the heater trace located within a pin field of the corresponding socket location.

4. The apparatus of claim 1, further comprising:
a power supply coupled to each of the heating elements via the first and second voltage supply lines to provide power thereto; and
a power supply controller coupled to the power supply to control the power supply.

5. The apparatus of claim 4, further comprising a temperature sensor associated with each burn-in socket to provide temperature information regarding the heating element and the semiconductor DUT.

6. The apparatus of claim 5, further comprising a temperature processor coupled to the temperature sensors to individually control a temperature of each of the heating elements based on the temperature information from the corresponding temperature sensor, via control signals provided to the power supply controller.

7. The apparatus of claim 4, wherein the power supply comprises a secondary power supply, wherein the secondary power supply is to provide power to the semiconductor DUTs if the semiconductor DUTs are high power devices, and to provide power to the heating elements if the semiconductor DUTs are low power devices.

8. The apparatus of claim 5, wherein the heating element is to be enabled if the corresponding semiconductor DUT has a power level less than a predetermined threshold, otherwise the heating element is to be disabled.

9. A method comprising:
measuring a temperature of a semiconductor device under test (DUT) coupled within a burn-in socket affixed to a burn-in board, using a temperature sensor associated with the burn-in socket;
providing feedback information regarding the temperature to a temperature processor of a control unit coupled to the burn-in board;
comparing the temperature to a threshold level; and
applying power to a heater element embedded within a layer of the burn-in board associated with the burn-in socket, if the temperature is below the threshold level.

10. The method of claim 9, further comprising providing the feedback information regarding the heater element and the semiconductor DUT from a temperature sensor associated with each burn-in socket to a temperature processor.

11. The method of claim 10, further comprising individually controlling a temperature of each of the heater elements based on the feedback information from the corresponding temperature sensor.

12. The method of claim 9, further comprising providing the power from a secondary power supply to the semiconductor DUT if the semiconductor DUT is a high power device, otherwise providing the power from the secondary power supply to the heater element if the corresponding semiconductor DUT is a low power device.

13. The method of claim 10, further comprising enabling the heater element if the corresponding semiconductor DUT has a power level less than a predetermined threshold, otherwise disabling the heater element.
